(19) United States
(12) Patent Application Publication
(10) Pub. No.: US 2020/0399118 A1
(43) Pub. Date: Dec. 24, 2020

(54) ELECTRONIC DEVICE

(71) Applicant: DENSO CORPORATION, Kariya-city (JP)

(72) Inventors: Yutaka HAYAKAWA, Kariya-city (JP); Hisanori YOKURA, Kariya-city (JP)

(21) Appl. No.: 17/011,062

(22) Filed: Sep. 3, 2020

Related U.S. Application Data
(63) Continuation of application No. PCT/JP2019/008659, filed on Mar. 5, 2019.

(30) Foreign Application Priority Data
Mar. 6, 2018 (JP) 2018-039959

(51) Int. Cl. B81B 7/00; H01L 23/00; G01L 13/06

(52) U.S. Cl. CPC B81B 7/0048; F01N 11/002; H01L 24/48; G01L 13/06; H01L 2224/48137; H01L 2224/48227; H01L 2224/48463; H01L 2224/48491; H01L 2224/48644; H01L 2224/48744; H01L 2924/1461; H01L 2924/3512; B81B 2201/0264; B81B 2203/0127; B81B 2207/012; B81B 2207/098; B81B 7/007

(57) ABSTRACT

A electronic device includes a substrate, a first metal film, an insulating film, a second metal film, and a third metal film. The substrate has one surface. The first metal film is disposed on the one surface. The insulating film is disposed on the one surface in a state covering the first metal film. The insulating film has a contact hole exposing the first metal film. The second metal film is disposed on a portion of the first metal film exposed from the contact hole and a periphery of the contact hole. The third metal film is made of gold and disposed on the second metal film. The first metal film, the second metal film, and the third metal film are stacked as a pad portion.

### CROSS REFERENCE TO RELATED APPLICATIONS

The present application is a continuation application of International Patent Application No. PCT/JP2019/008659 filed on Mar. 5, 2019, which designated the U.S. and claims the benefit of priority from Japanese Patent Application No. 2018-039959 filed on Mar. 6, 2018. The entire disclosures of all of the above applications are incorporated herein by reference.

### TECHNICAL FIELD

The present disclosure relates to an electronic device in which a bonding wire is connected to a pad portion.

### BACKGROUND

A pressure sensor has been proposed as an electronic device in which a bonding wire is connected to a pad portion provided on a sensor chip.

### SUMMARY

The present disclosure provides an electronic device. The electronic device includes a substrate, a first metal film, an insulating film, a second metal film, and a third metal film. The substrate has one surface. The first metal film is disposed on the one surface. The insulating film is disposed on the one surface in a state covering the first metal film. The insulating film has a contact hole exposing the first metal film. The second metal film is disposed on a portion of the first metal film exposed from the contact hole and a periphery of the contact hole. The third metal film is made of gold and disposed on the second metal film. The first metal film, the second metal film, and the third metal film are stacked as a pad portion.

### BRIEF DESCRIPTION OF DRAWINGS

The features and advantages of the present disclosure will become more apparent from the following detailed description made with reference to the accompanying drawings. In the drawings:

FIG. 1 is a perspective view showing a configuration of a pressure sensor according to a first embodiment;

FIG. 2 is a cross-sectional view taken along a line II-II shown in FIG. 1;

FIG. 3 is a cross-sectional view of a vicinity of a pad portion formed in the sensor chip of FIG. 1;

FIG. 4 is a plan view showing an insulating film and a first metal film in a vicinity of a contact hole formed in the insulating film in FIG. 3;

FIG. 5 is a plan view showing an insulating film and a first metal film in a vicinity of a contact hole formed in the insulating film according to a modified example of the first embodiment;

FIG. 6 is a plan view showing an insulating film and a first metal film in a vicinity of a contact hole formed in the insulating film according to a second embodiment;

FIG. 7 is a plan view showing an insulating film and a first metal film in a vicinity of a contact hole formed in the insulating film according to a third embodiment;

FIG. 8 is a plan view showing an insulating film and a first metal film in a vicinity of a contact hole formed in the insulating film in a modified example of the embodiment;

FIG. 9 is a plan view showing an insulating film and a first metal film in a vicinity of a contact hole formed in the insulating film according to a fourth embodiment;

FIG. 10 is a diagram showing a relationship between a film thickness of a third metal film and the number of pinholes; and

FIG. 11 is a diagram showing a relationship between the film thickness of the third metal film and shear strength.

### DETAILED DESCRIPTION

For example, a pressure sensor as an electronic device includes a sensor chip having one surface, and a pressure detection element is disposed on one surface. The pressure sensor includes a first metal film disposed on the one surface, and the first metal film is covered by an insulating film. The insulating film includes a contact hole having an opening end that has a rectangular shape. The contact hole exposes a predetermined region of the first metal film. A second metal film is disposed on a portion of the first metal film exposed from the contact hole. The second metal film is also disposed around the contact hole of the insulating film. The pad portion is provided by a stack of the first metal film and the second metal film.

In the above-described electronic device, when the pad portion is broken, the electronic device does not function as a sensor. Thus, it is desired to improve the reliability of the pad portion.

The present disclosure provides an electronic device that can improve reliability of a pad portion.

An exemplary embodiment of the present disclosure provides an electronic device that includes a substrate, a first metal film, an insulating film, a second metal film, and a third metal film. The substrate has one surface. The first metal film is disposed on the one surface. The insulating film is disposed on the one surface in a state covering the first metal film. The insulating film has a contact hole exposing the first metal film. The second metal film is disposed on a portion of the first metal film exposed from the contact hole and a periphery of the contact hole. The third metal film is made of gold and disposed on the second metal film. The first metal film, the second metal film, and the third metal film are stacked as a pad portion. The second metal film is covered by the third metal film without being exposed from the third metal film. The third metal film has a film thickness of equal to or more than 0.4 μm.

In the exemplary embodiment of the present disclosure, the number of pinholes in the third metal film can be reduced, and the shear strength can be increased. That is, the reliability of the pad portion can be improved.

Another exemplary embodiment of the present disclosure provides an electronic device that includes a substrate, a first metal film, an insulating film, a second metal film, and a third metal film. The substrate has one surface. The first metal film is disposed on the one surface. The insulating film is disposed on the one surface in a state covering the first metal film. The insulating film has a contact hole exposing the first metal film. The second metal film is disposed on a portion of the first metal film exposed from the contact hole and a periphery of the contact hole. The third metal film is made of gold and disposed on the second metal film. The insulating film includes a stress reduction structure. The first metal film, the second metal film, and the third metal film are stacked as a pad portion. The second metal film is covered by the third metal film without being exposed from the third metal film. The third metal film has a film thickness of equal to or more than 0.4 μm.

In another exemplary embodiment of the present disclosure, the stress reduction structure suppresses the pad portion from being broken and improve the reliability of the pad portion.

Hereinafter, embodiments of the present disclosure will be described with reference to the drawings. In each embodiment described below, same or equivalent parts are designated with the same reference numerals.

### First Embodiment

A first embodiment will be described with reference to the drawings. In the present embodiment, an example in which an electronic device is applied to a pressure sensor will be described. The pressure sensor of the present embodiment may be attached to a diesel particulate filter (hereinafter, referred to as a DPF) provided in an exhaust pipe of a diesel engine in order to detect a pressure loss of the diesel engine. The pressure sensor is provided as a pressure sensor of differential pressure detection type that detects the differential pressure between an upstream pressure of the DPF and a downstream pressure of the DPF.

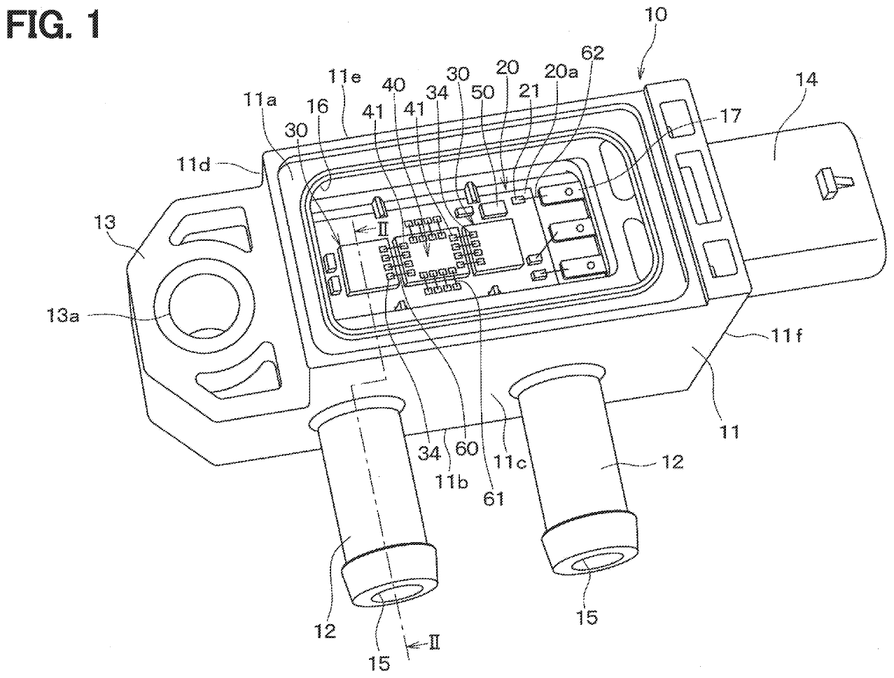

As shown in FIG. 1, the pressure sensor of the present embodiment includes a case 10 formed by molding polyphenylene sulfide (that is, PPS), polybutylene terephthalate (that is, PBT), epoxy resin, or the like. In addition, in FIG. 1, a lid portion 80 described later is omitted.

The case 10 of the present embodiment includes a main body portion 11, a port portion 12, an assembling portion 13, a connector portion 14, and the like. The port portion 12, the assembling portion 13, the connector portion 14 are provided in the main body portion 11. Specifically, the main body portion 11 has a substantially rectangular parallelepiped shape. The main body portion 11 has one surface 11a, another surface 11b, and first to fourth side surfaces 11c to 11f connecting the one surface 11a and another surface 11b.

Two port portions 12 are provided on the first side surface 11c of the main body portion 11 so as to extend along the normal direction of the first side surface 11c. The assembling portion 13 is provided on the second side surface 11d of the main body portion 11. The connector portion 14 is provided on the fourth side surface 11f of the main body portion 11 and has a tubular shape having a cavity inside.

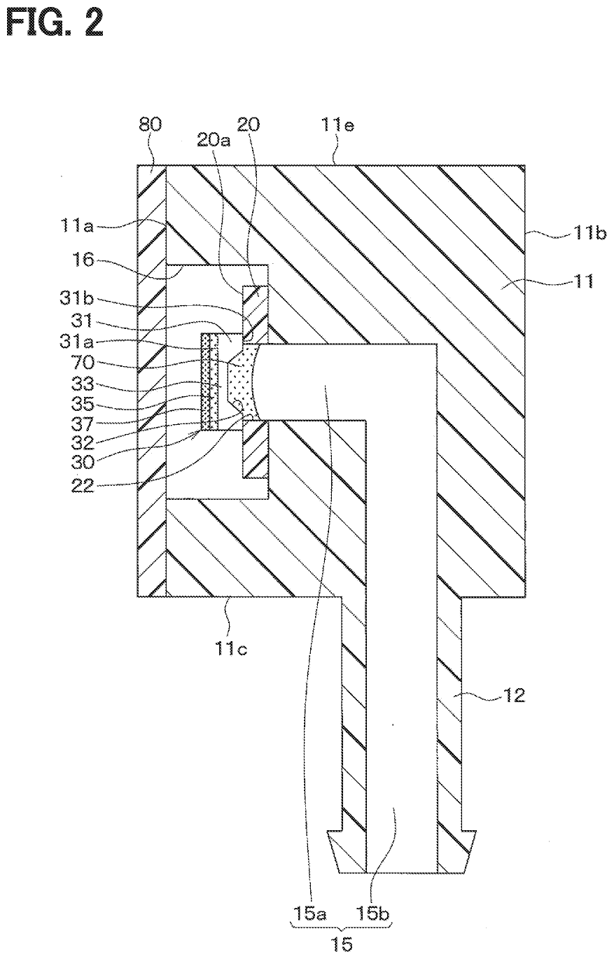

Further, as shown in FIGS. 1 and 2, the case 10 is provided with a pressure introduction hole 15 into which a measurement medium is introduced. The pressure introduction hole 15 is configured by connecting a first introduction hole 15a formed in the main body portion 11 and a second introduction hole 15b formed in the main body portion 11 and the port portion 12.

Specifically, in the case 10, a recess 16 is formed on one surface 11a of the main body portion 11, and the first introduction hole 15a is formed from the bottom surface of the recess 16 toward another surface 11b. The second introduction hole 15b penetrates the port portion 12, is also formed in the main body portion 11 along the extending direction of the port portion 12. The second introduction hole 15b is connected to the first introduction hole 15a. In the present embodiment, the pressure introduction hole 15 penetrating the case 10 is formed as described above.

In the recess 16 formed in the main body portion 11, a wiring board 20 provided by a printed board or the like is mounted via an adhesive (not shown). On the wiring board 20, two sensor chips 30, a circuit chip 40, and a plurality of electronic components 50 such as a capacitor are mounted on one surface 20a opposite to the case 10. Further, the wiring board 20 has a plurality of pad portions 21 provided on the one surface 20a, and two through holes 22 connecting to each pressure introduction hole 15 are formed.

Each sensor chip 30 includes a silicon substrate 31 having a rectangular plate shape. A diaphragm 33 on one surface 31a of the silicon substrate 31 is provided by forming a recess 32 on another surface 31b of the silicon substrate 31. A gauge resistor (not shown) is provided on the silicon substrate 31 so as to form a bridge circuit on the diaphragm 33. That is, the sensor chip 30 of the present embodiment is a semiconductor diaphragm type. The sensor chip 30 outputs a sensor signal according to the change of the voltage of the bridge circuit by changing the resistance value of the gauge resistance when the pressure is applied to the diaphragm 33. Further, the sensor chip 30 is provided with a pad portion 34 electrically connected to the circuit chip 40.

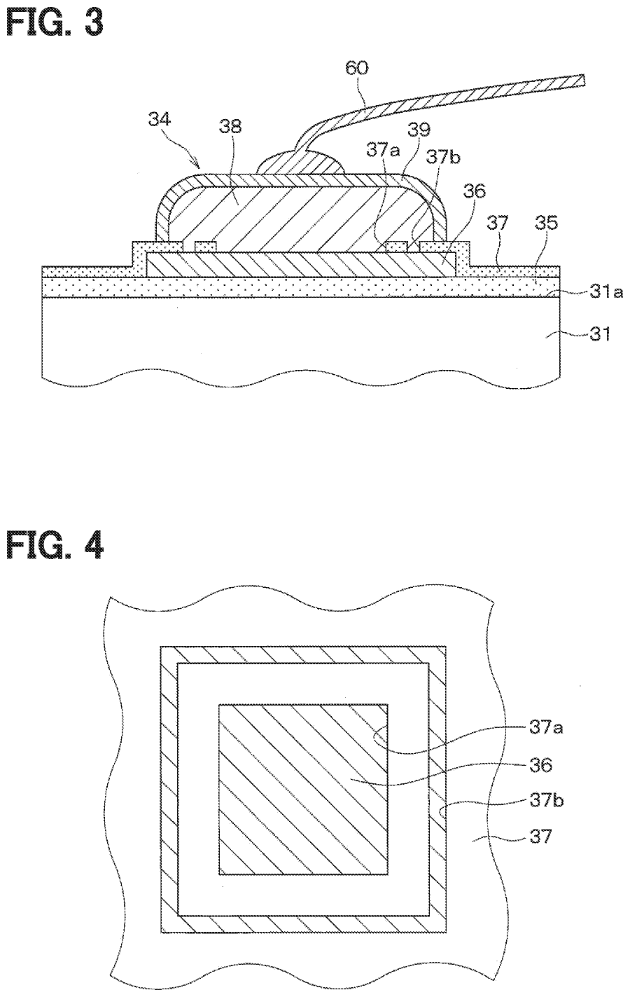

The configuration in a vicinity of the pad portion 34 in the present embodiment will be specifically described with reference to FIGS. 3 and 4. Although FIG. 4 is a plan view showing an arrangement relationship between a first metal film 36 and an insulating film 37 in a vicinity of a contact hole 37a, the first metal film 36 is hatched to be easily understood.

The silicon substrate 31 includes a protective film 35 made of a nitride film or the like on the one surface 31a. Then, a first metal film 36 is formed on the surface of the protective film 35. A contact hole is formed in the protective film 35 in a cross section different from that of FIG. 3. The first metal film 36 is electrically connected to the gauge resistor through the contact hole formed in the protective film 35. That is, the first metal film 36 is a metal film that functions as a wiring portion, and is appropriately routed over the protective film 35. In the present embodiment, the first metal film 36 is made of, for example, aluminum or an alloy containing aluminum as a main component.

An insulating film 37 provided by an oxide film or the like is formed on the surface of the protective film 35 so as to cover the first metal film 36. Then, the insulating film 37 is provided with a contact hole 37a exposing a predetermined region of the first metal film 36. In addition, in the present embodiment, the contact hole 37a is provided by an opening end having a flat rectangular shape.

Then, a second metal film 38 is formed on the first metal film 36. Specifically, a second metal film 38 is formed on the first metal film 36 exposed from the contact hole 37a and on a portion of the insulating film 37 around the contact hole 37a. In other words, the portion of the insulating film 37 that surrounds the contact hole 37a is sandwiched between the first metal film 36 and the second metal film 38. The second metal film 38 is made of, for example, nickel or an alloy containing nickel as a main component.

In addition, in the present embodiment, the insulating film 37 includes a slit 37b formed in a portion located between the first metal film 36 and the second metal film 38. In the present embodiment, the slit 37b has a frame shape surrounding the contact hole 37a and is formed so as to expose the first metal film 36. That is, the first metal film 36 of the present embodiment is exposed from the contact hole 37a and the slit 37b. In the present embodiment, the slit 37b corresponds to a stress reduction structure.

Then, as shown in FIG. 3, the second metal film 38 is also disposed in the slit 37b and is in contact with the first metal film 36. A third metal film 39 is disposed on the second metal film 38 so as to cover the surface of the second metal film 38. The third metal film 39 is made of a material having corrosion resistance, for example, gold or an alloy containing gold as a main component. Then, in the present embodiment, the pad portion 34 is provided by a stack of the first metal film 36, the second metal film 38, and the third metal film 39 as described above.

The above description is the configuration of the sensor chip 30 in the present embodiment. The bonding wire 60 is connected to the third metal film 39 and the pad portion 34 is electrically connected to the circuit chip 40 via the bonding wire 60. The bonding wire 60 is made of gold, aluminum or the like.

Then, as shown in FIG. 2, each sensor chip 30 is attached to the wiring board 20 via an adhesive (not shown) in a state where another surface 31b of the silicon substrate 31 is faced toward the wiring board 20 so as to close each through hole 22 formed in the wiring board 20. As a result, the measurement medium introduced in the pressure introduction hole 15 is applied to the sensor chip 30.

The circuit chip 40 includes a control circuit for outputting a drive signal to each sensor chip 30 and a detection signal to the outside, and outputting a sensor signal, which is received from the sensor chip 30, to the outside by amplifying the sensor signal and performing an arithmetic process. The circuit chip 40 includes a plurality of pad portions 41, and a part of the plurality of pad portions 41 is electrically connected to the pad portion 34 of the sensor chip 30 via the bonding wire 60. The rest of the plurality of pad portions 41 is electrically connected to the pad portion 21 formed on the wiring board 20 via the bonding wire 61. Although not particularly limited, the circuit chip 40 is mounted between the two sensor chips 30.

A gel protective member 70 is arranged in each through hole 22 of the wiring board 20 and in the recess 32 of the sensor chip 30. The protective member 70 protects the wiring board 20 and the sensor chip 30 from the corrosive gas and humidity included in the measurement medium. That is, in the present embodiment, the pressure of the measurement medium is applied to the diaphragm 33 via the protective member 70.

The protective member 70 may be provided by fluorine gel, silicon gel, fluorosilicon gel, or the like. In particular, when the exhaust gas pressure is measured as the measurement medium, the condensed water due to the exhaust gas has strong acidity due to the dissolution of nitrogen oxides and sulfur oxides contained in the exhaust gas. Therefore, it is preferable that the protective member 70 is provided by a fluorine gel having strong acid resistance.

Further, as shown in FIG. 1, the case 10 is provided with a plurality of metal terminals 17. Each terminal 17 is supported in the case 10 by being integrally molded with the case 10 by insert molding.

Specifically, each terminal 17 is supported so as to penetrate the case 10. One end of each terminal 17 protrudes in the recess 16 and the other end of each terminal 17 protrudes in the connector portion 14. One end of the terminal 17 protruding in the recess 16 is electrically connected to the pad portion 21 formed on the wiring board 20 via the bonding wire 62. The other end of the terminal 17 protruding in the connector portion 14 is exposed in the connector portion 14 and is electrically connected to an external wiring member or the like.

Furthermore, as shown in FIG. 2, the case 10 is provided with a lid portion 80 so as to close the recess 16. In the present embodiment, the lid portion 80 is made of polyphenylene sulfide, polybutylene terephthalate, epoxy resin or the like, and is provided on the case 10 via an adhesive or the like. As a result, the space surrounded by the recess 16 and the lid portion 80 is sealed to form a reference pressure chamber.

Further, as shown in FIG. 1, the assembling portion 13 of the case 10 has a fixing hole 13a through which a screw member such as a bolt is inserted when the assembling portion 13 is attached to a member to be attached. The fixing hole 13a penetrates in the normal direction of the one surface 11a. The fixing hole 13a is formed by fitting a metal ring into the wall surface of a through hole formed in the resin that constitutes the assembling portion 13.

The above is the configuration of the pressure sensor in the present embodiment. Next, the operation of the pressure sensor will be described.

The pressure sensor is installed, for example, so that the exhaust gas on the upstream side of the DPF is introduced into one of the pressure introduction holes 15 and the exhaust gas on the downstream side of the DPF is introduced into the other side of the pressure introduction hole 15. As a result, one sensor chip 30 detects the upstream pressure and the other sensor chip 30 detects the downstream pressure. Then, the circuit chip 40 calculates the difference between the upstream pressure and the downstream pressure, and outputs the calculation result to the external circuit via the terminal 17. Therefore, the differential pressure of the exhaust pipe before and after the DPF is detected from the calculation result.

As described above, in the present embodiment, the slit 37b that exposes the first metal film 36 is formed in the portion of the insulating film 37 located between the first metal film 36 and the second metal film 38. Then, the second metal film 38 is also arranged in the slit 37b. Therefore, as compared with the case where the slit 37b is not formed in the insulating film 37, it is possible the pad portion 34 to avoid being broken by the introduction of a crack in the first metal film 36. That is, the reliability of the pad portion 34 can be improved.

That is, in the sensor chip 30 as described above, the first metal film 36 has a portion (hereinafter, referred to as a triple point portion) in contact with the insulating film 37 and the second metal film 38. In this case, in a sensor chip in which the slit 37b is not formed as a comparison example (hereinafter referred to as a comparison sensor chip), an end of portion of the first metal film 36 exposed from the contact hole 37a becomes the triple point portion. Then, in the triple point portion of the first metal film 36, a large stress is applied due to thermal contraction and thermal expansion of the insulating film 37 and the second metal film 38, and the crack is easily introduced.

However, in this embodiment, the slit 37b is formed in the insulating film 37, and the second metal film 38 is also arranged in the slit 37b. Therefore, in the present embodiment, the end of the portion of the first metal film 36 exposed from the contact hole 37a and the end of the portion exposed from the slit 37b are triple point portion. Therefore, in the present embodiment, the triple point portion of the first metal film 36 can be increased, and the stress generated per unit portion of the triple point portion can be reduced. As a result, it is possible to avoid introducing the crack into the first metal film 36 and improve the reliability of the pad portion 34.

### Modification of First Embodiment

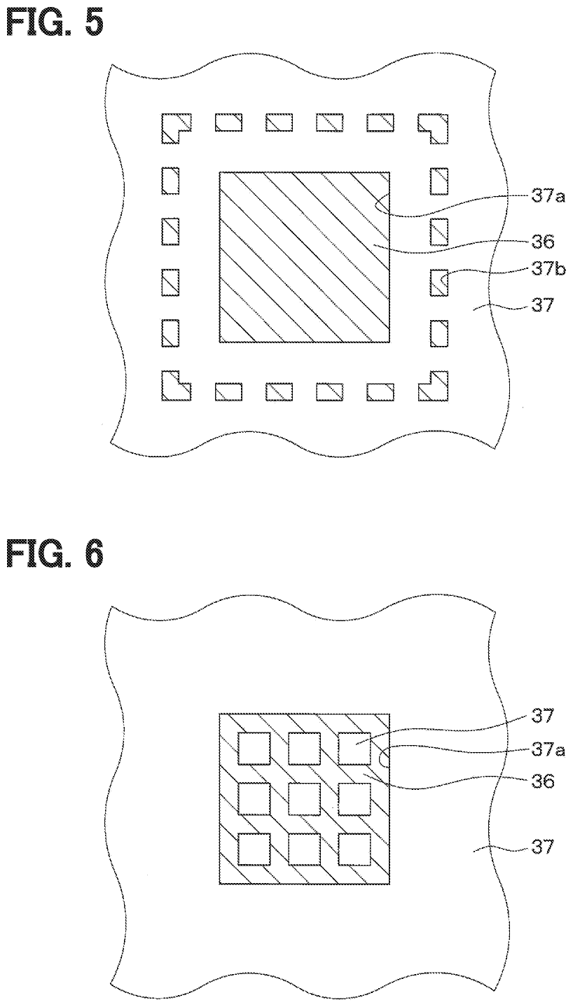

A modification example of the above-described first embodiment will be described hereafter. In the first embodiment, the slit 37b is not limited to have the frame shape. For example, as shown in FIG. 5, the slit 37b may be divided into a plurality of parts. That is, the slit 37b may be formed in a dotted line shape. Although FIG. 5 is a plan view showing an arrangement relationship between the first metal film 36 and the insulating film 37 in a vicinity of the contact hole 37a, the first metal film 36 is hatched to be easily understood.

### Second Embodiment

A second embodiment will be described. In this embodiment, the shape of the contact hole 37a formed in the insulating film 37 is changed from that of the first embodiment. Other components are the same as those of the first embodiment, and therefore a description of those components will be omitted.

In this embodiment, as shown in FIG. 6, the contact hole 37a is formed in a lattice pattern. That is, the contact hole 37a is formed so that the insulating films 37 remain in the contact hole 37a. In the present embodiment, the contact hole 37a is formed so that the insulating films 37 remain in dot shapes in the contact hole 37a.

Although FIG. 6 is a plan view showing an arrangement relationship between the first metal film 36 and the insulating film 37 in a vicinity of the contact hole 37a, the first metal film 36 is hatched to be easily understood. Further, in the present embodiment, the insulating films 37 existing in the contact hole 37a correspond to a stress reduction structure. In other words, in this embodiment, the contact hole 37a having the lattice shape corresponds to the stress reduction structure.

Even with the contact hole 37a as described above, the triple point portion of the first metal film 36 can be increased as compared with a contact hole of the comparison sensor chip. Thus, the same effect as that of the first embodiment can be obtained.

### Third Embodiment

A third embodiment will be described. In this embodiment, the shape of the contact hole 37a formed in the insulating film 37 is changed from that of the first embodiment. Other components are the same as those of the first embodiment, and therefore a description of those components will be omitted.

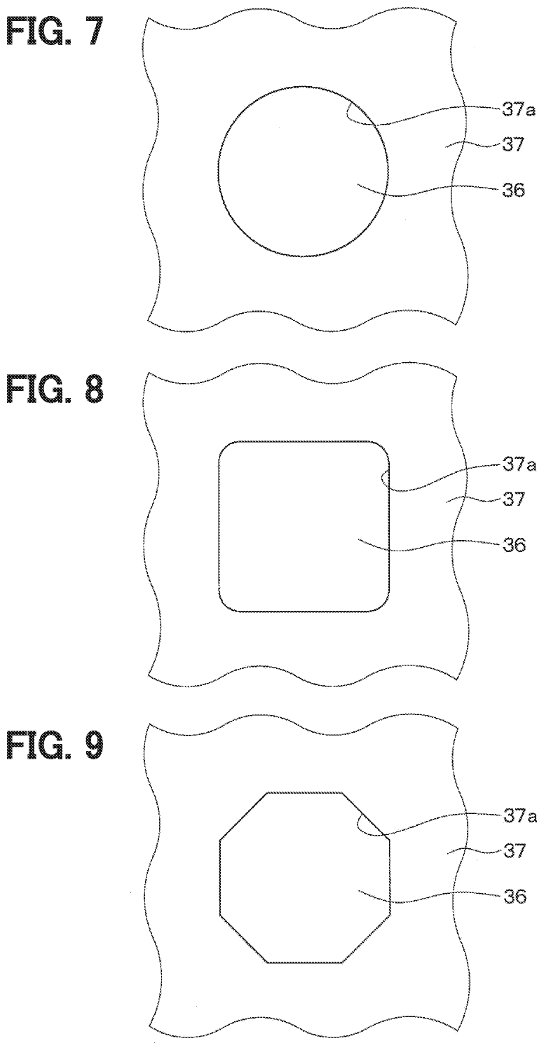

As shown in FIG. 7, the contact hole 37a of the present embodiment has a cylindrical shape with a circular opening end. That is, the contact hole 37a is configured to have no corners. In other words, in this embodiment, the shape of the contact holes 37a corresponds to the stress reduction structure.

Such a contact hole 37a does not have a corner as compared with a contact hole having an opening end in a rectangular shape. Thus, stress can be suppressed from being concentrated at a specific portion of the contact hole 37a. Therefore, it is possible to suppress the crack from being introduced into the first metal film 36, and it is possible to obtain the same effect as that of the first embodiment.

### Modification of Third Embodiment

The modification of the first embodiment will be described below. In the third embodiment, as shown in FIG. 8, the contact hole 37a may have a plurality of side surfaces having different directions, and the portion connecting adjacent two of the side surfaces may be a curved surface. In other words, the contact hole 37a may have chamfered corners. Even with such a contact hole 37a, it is possible to suppress stress from concentrating on a specific portion of the contact hole 37a, and thus it is possible to obtain the same effect as that of the third embodiment.

### Fourth Embodiment

A fourth embodiment will be described. In this embodiment, the shape of the contact hole 37a formed in the insulating film 37 is changed from that of the first embodiment. Other components are the same as those of the first embodiment, and therefore a description of those components will be omitted.

As shown in FIG. 9, the contact hole 37a of the present embodiment has an octagonal tube shape with an opening end having an octagonal shape. In other words, in this embodiment, the shape of the contact holes 37a corresponds to the stress reduction structure.

Although the contact hole 37a has a shape having corners, the number of corners is larger than that of the contact hole having a rectangular shape, and the stress generated at one corner can be reduced. Therefore, it is possible to suppress a crack from being introduced into the first metal film 36, and it is possible to obtain the same effect as that of the first embodiment.

In this embodiment, the case where the opening end of the contact hole 37a has an octagonal shape has been described as an example. The effect of the present embodiment can be obtained if the contact hole 37a has a larger number of corners than the case where the opening end is rectangular. Thus, the contact hole 37a may have an opening end of a polygonal shape having equal to or more than five vertices.

### Fifth Embodiment

In this embodiment, the film thickness of the third metal film 39 is defined as compared with the first embodiment. The other configurations are the same as those of the first embodiment, and therefore a description of the same configurations will be omitted below.

The structure of the pressure sensor of the present embodiment is basically the same as that of the first embodiment, but the slit 34b is not formed. In the present embodiment, the third metal film 39 is provided by a gold film, and the film thickness is defined.

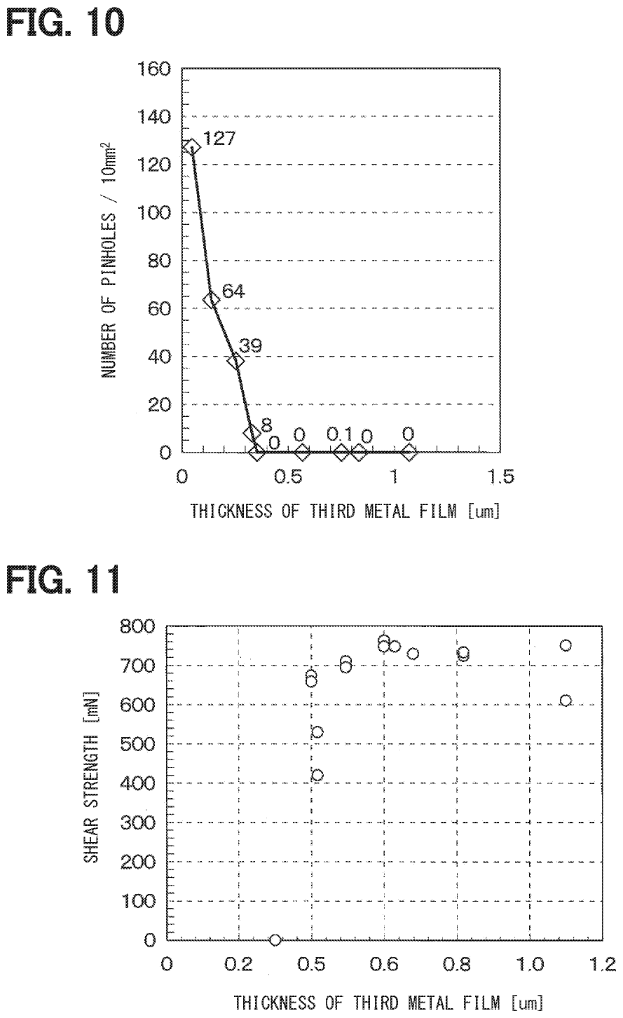

Here, the inventor focused on the relationship between the film thickness of the third metal film 39 and the number of pinholes formed in the third metal film 39, and performed a nitric acid detonation test to obtain the result shown in FIG. 10. The pinhole constitutes a passage through which a corrosive medium including chlorine or the like reaches the second metal film 38. Therefore, the larger the number of pinholes, the more easily the second metal film 38 is corroded. As shown in FIG. 10, the number of the pinholes sharply increases when the thickness of the third metal film 39 is less than 0.4 μm, and the pinhole is almost not formed when the thickness of the third metal film 39 is equal to or more than 0.4 μm.

In addition, the inventor focused on the relationship between the film thickness of the third metal film 39 and the shear strength and conducted a tensile test to obtain the results shown in FIG. 11. As shown in FIG. 11, the shear strength sharply increases at equal to or more than 0.4 μm. In comparison with the result shown in FIG. 10, it is presumed that this is because the pinholes are almost absent in the third metal film 39, so that the corrosion of the second metal film 38 is suppressed, and it is difficult for the part in the third metal film 39 that becomes the starting point of destruction to exist.

Therefore, in the present embodiment, the third metal film 39 has a film thickness of equal to or more than 0.4 μm.

As described above, in the present embodiment, the third metal film 39 is made of a gold film and has a film thickness of equal to or more than 0.4 μm. Therefore, the number of pinholes in the third metal film 39 can be reduced, and the shear strength can be increased. Therefore, it is possible to suppress the pad portion 34 from being broken and improve the reliability of the pad portion 34.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combination and formation, and other combination and formation including one, more than one or less than one element may be made in the present disclosure.

For example, in each of the above embodiments, the pressure sensor has been described as an example. However, each of the above embodiments may be applied to an acceleration sensor or an angular velocity sensor.

Further, in each of the above-described embodiments, the pad portion 34 formed on the sensor chip 30 has been described. However, each of the above embodiments may be applied to the pad portion 21 of the wiring board 20, the pad portion 41 of the circuit chip 40, and the like.

Further, in the above-described first to fourth embodiments, the third metal film 39 may not be provided.

In the second embodiment, the insulating films 37 remaining in the contact hole 37a do not have to be arranged in dot shapes. The shape of the insulating films 37 remaining in the contact hole 37a can be appropriately changed.

Then, in the fifth embodiment, the third metal film 39 may be made of an alloy containing gold as a main component. As described above, even when the third metal film 39 is made of the alloy containing gold as the main component, by setting the thickness of the third metal film 39 to equal to or more than 0.4 μm, the same effect as that of the fifth embodiment can be obtained.

Furthermore, the embodiments described above can be combined together as appropriate. For example, the first embodiment may be combined with the fifth embodiment to form the slit 37b in the insulating film 37. Further, the second embodiment may be combined with the third to fifth embodiments to cause the contact holes 37a have a lattice shape. When the second embodiment is combined with the third or fourth embodiment, the insulating film 37 is left in the contact hole 37a, and the outermost portion of the contact hole 37a has the shape of the third or fourth embodiment. Further, by combining the third or fourth embodiment with the fifth embodiment, the contact hole 37a may have a circular opening end, or may have a polygonal shape with a pentagonal shape or more.

What is claimed is:

1. An electronic device comprising:
a substrate having one surface;
a first metal film disposed on the one surface;
an insulating film disposed on the one surface in a state covering the first metal film, and having a contact hole exposing the first metal film;
a second metal film disposed on a portion of the first metal film exposed from the contact hole and a periphery of the contact hole; and
a third metal film made of gold and disposed on the second metal film, wherein:
the first metal film, the second metal film, and the third metal film are stacked as a pad portion;
the second metal film is covered by the third metal film without being exposed from the third metal film; and
the third metal film has a film thickness of equal to or more than 0.4 pm.

2. An electronic device comprising:
a substrate having one surface;
a first metal film disposed on the one surface;
an insulating film disposed on the one surface in a state covering the first metal film, and having a contact hole exposing the first metal film;
a second metal film disposed on a portion of the first metal film exposed from the contact hole and a periphery of the contact hole; and
a third metal film made of gold and disposed on the second metal film, wherein:
the insulating film includes a stress reduction structure;
the first metal film, the second metal film, and the third metal film are stacked as a pad portion;
the second metal film is covered by the third metal film without being exposed from the third metal film; and
the third metal film has a film thickness of equal to or more than 0.4 pm.

3. The electronic device according to claim 2, wherein
the insulating film has, as the stress reduction structure, a slit disposed in a portion between the first metal film and the second metal film, and exposing the first metal film, and
the second metal film is disposed on a portion of the first metal film exposed from the slit.

4. The electronic device according to claim 2, wherein:
the insulating film has, as the stress reduction structure, the contact hole disposed in a state where the insulating film remains in the contact hole.

5. The electronic device according to claim 2, wherein:
the insulating film has, as the stress reduction structure, the contact hole having an opening end that has a circular shape.

6. The electronic device according to claim 2, wherein:
the insulating film has a plurality of side surfaces that provide the contact hole as the stress reduction structure; and
a surface that connects adjacent two of the plurality of side surfaces is provided by a curved surface.

7. The electronic device according to claim 2, wherein:
the insulating film has, as the stress reduction structure, the contact hole having an opening end of a polygonal shape having equal to or more than five vertices.
